(19) United States
(12) Patent Application Publication
(10) Pub. No.: US 2026/0305236 A1
(43) Pub. Date: Oct. 1, 2026

(54) SUBSTRATE HOLDER, SUBSTRATE PROCESSING APPARATUS, METHOD OF PROCESSING SUBSTRATE, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventors: Tatsuya NISHINO, Toyama (JP); Hajime SAKURAI, Toyama (JP)

(73) Assignee: KOKUSAI ELECTRIC CORPORATION, Tokyo (JP)

(21) Appl. No.: 19/568,417

(22) Filed: Mar. 16, 2026

(30) Foreign Application Priority Data
Mar. 26, 2025 (JP) 2025-052714

(51) Int. Cl. H10P 72/10; H10P 72/30

(52) U.S. Cl. CPC H10P 72/127; H10P 72/3412

(57) ABSTRACT

A technique includes a substrate holder including: a first boat holding substrates along a predetermined axis and a second boat movable in a direction of the axis, wherein the first and second boats respectively include first and second support columns extending in the direction of the axis and supporting the substrates from outer peripheries, the second boat configured such that the substrates are delivered from the first boat to the second boat and returned from the second boat to the first boat by moving the second boat in both directions along the axis, and wherein elastic deformation of at least one of the first and the second boat when supporting the substrates is set so that no displacement of the at least one of the first and the second boat occurs in a perpendicular direction of the axis after a cycle of delivery and return of the substrates is performed.

### CROSS-REFERENCE TO RELATED APPLICATION

This application is based upon and claims the benefit of priority from Japanese Patent Application No. 2025-052714, filed on Mar. 26, 2025, the entire content of which is incorporated herein by reference.

### TECHNICAL FIELD

The present disclosure relates to a substrate holder, a substrate processing apparatus, a method of processing a substrate, a method of manufacturing a semiconductor device, and a recording medium.

### BACKGROUND

In the related art, in a substrate processing apparatus as a semiconductor manufacturing apparatus for processing semiconductor substrates (also called workpieces or wafers), a boat, which is a substrate support storing a large number of semiconductor substrates, is disposed inside a vertical process furnace to perform a film formation process.

Substrates may be displaced horizontally due to deflection of a main boat (first boat) and a sub boat (second boat) when the substrates are supported by the first boat and the second boat.

### SUMMARY

Some embodiments of the present disclosure provide a technique capable of reducing horizontal misalignment of substrates caused by deflection of a first boat and a second boat when the substrates are supported by the first boat and the second boat.

According to some embodiments of the present disclosure, there is provided a technique that includes a substrate holder including: (a) a first boat configured to hold a plurality of substrates arranged along a predetermined axis; and (b) a second boat configured to be movable in a direction of the axis relative to the first boat, wherein the first boat includes (a1) a plurality of first support columns extending in the direction of the axis and supporting the plurality of substrates from outer peripheral sides of the substrates, wherein the second boat includes (b1) a plurality of second support columns extending in the direction of the axis and supporting the plurality of substrates from the outer peripheral sides of the substrates, the second boat being configured such that the plurality of substrates are delivered from the first boat to the second boat and returned from the second boat to the first boat by moving the second boat relative to the first boat in both directions along the axis, and wherein an amount and a direction of elastic deformation of at least one selected from the group of the first boat and the second boat when supporting the plurality of substrates are set so that substantially no displacement of the at least one selected from the group of the first boat and the second boat occurs in a perpendicular direction with respect to the direction of the axis of the plurality of substrates after a cycle including the delivery and return of the plurality of substrates is performed one or more times.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus suitably used in one embodiment of the present disclosure, in which a portion of the process furnace is illustrated in a vertical sectional view.

FIG. 2 is a schematic configuration diagram of the vertical process furnace of the substrate processing apparatus suitably used in one embodiment of the present disclosure, in which a portion of the process furnace is illustrated in a sectional view taken along line A-A in FIG. 1.

FIG. 3 is a perspective view of a first boat suitably used in one embodiment of the present disclosure.

FIG. 4 is a perspective view of a second boat suitably used in one embodiment of the present disclosure.

FIG. 5 is a horizontal sectional view of the first boat and the second boat preferably used in one embodiment of the present disclosure, which are combined together.

FIG. 6 is a schematic configuration diagram of a controller for the substrate processing apparatus suitably used in one embodiment of the present disclosure, in which the control system of the controller is shown in a block diagram.

FIG. 7 is a diagram showing a process flow in one embodiment of the present disclosure.

FIGS. 8A to 8D are diagrams explaining wafer misalignment in a boat according to a comparative example.

FIG. 9 is a perspective view of a first boat and a second boat according to a modification suitably used in one embodiment of the present disclosure.

FIG. 10 is a diagram explaining an assembly of the first boat and second boat shown in FIG. 9.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are been described in detail so as not to unnecessarily obscure aspects of the various embodiments.

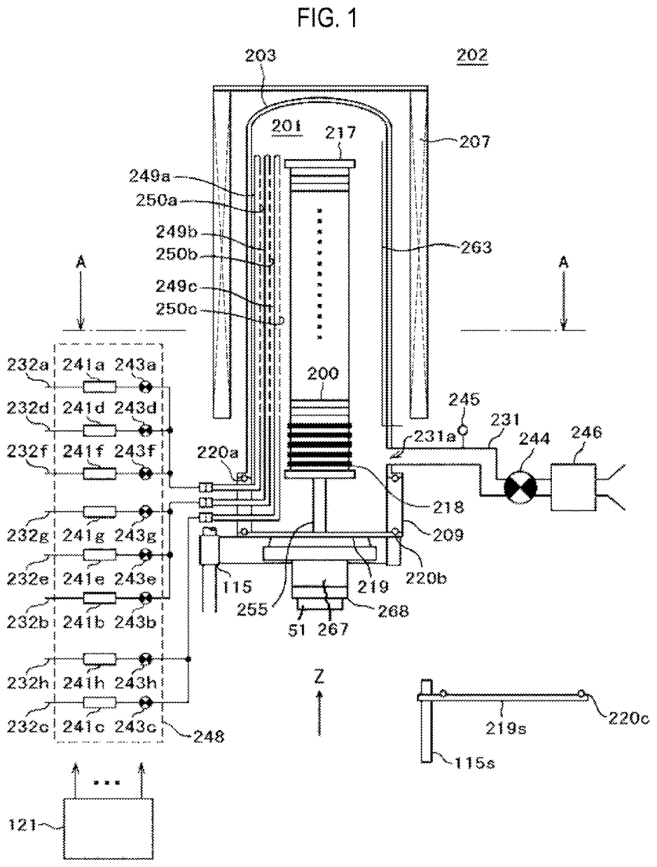

Hereinafter, one embodiment of the present disclosure will be described mainly with reference to FIGS. 1 to 8D. The drawings used in the following description are schematic, and the dimensional relationship of each element, the ratio of each element, and the like shown in the drawings do not necessarily match the actual ones. Moreover, the dimensional relationship of each element, the ratio of each element, and the like do not necessarily match between a plurality of drawings.

### (1) Configuration of Processing Apparatus

As shown in FIG. 1, a process furnace 202 includes a heater 207 as a temperature regulator (heating part). The heater 207 is formed in a cylindrical shape and is vertically installed by being supported by a support plate. The heater 207 functions as an activator (exciter) configured to thermally activate (excite) a gas.

Inside the heater 207, a reaction tube 203 is disposed concentrically with the heater 207. The reaction tube 203 is made of a heat-resistant material such as, for example, quartz (SiO₂) or silicon carbide (SiC) and is formed in a cylindrical shape with a closed upper and an open lower end. Below the reaction tube 203, a manifold 209 is disposed concentrically with the reaction tube 203. The manifold 209 is made of a metallic material such as stainless steel (SUS) or the like and is formed in a cylindrical shape with open upper and lower ends. The upper end of the manifold 209 engages with the lower end of the reaction tube 203 so as to support the reaction tube 203. An O-ring 220a is installed as a seal between the manifold 209 and the reaction tube 203. The reaction tube 203 is installed vertically in the same manner as the heater 207. A process container (reaction container) is mainly constituted by the reaction tube 203 and the manifold 209. A process chamber 201 is formed in a hollow cylindrical region of the process container. The process chamber 201 is configured to be capable of accommodating wafers 200 which serve as substrates. The wafers 200 as semiconductor substrates are processed in the process chamber 201.

Nozzles 249a to 249c as first to third suppliers are installed in the process chamber 201 so as to penetrate a side wall of the manifold 209. The nozzles 249a to 249c are also referred to as first to third nozzles, respectively. The nozzles 249a to 249c are made of, for example, a heat-resistant material such as quartz or SiC. Gas supply pipes 232a to 232c are connected to the nozzles 249a to 249c, respectively. The respective nozzles 249a to 249c are different nozzles, and each of the nozzles 249a and 249c is installed adjacent to the nozzle 249b.

At the gas supply pipes 232a to 232c, mass flow controllers (MFCs) 241a to 241c, which are flow rate controllers (flow control parts), and valves 243a to 243c, which are opening/closing valves, are respectively installed in this order from an upstream side of a gas flow. Gas supply pipes 232d and 232f are connected to the gas supply pipe 232a at a downstream side of the valve 243a. Gas supply pipes 232e and 232g are connected to the gas supply pipe 232b at a downstream side of the valve 243b. A gas supply pipes 232h is connected to the gas supply pipe 232c at a downstream side of the valve 243c. On the gas supply pipes 232d to 232h, MFCs 241d to 241h and valves 243d to 243h are respectively installed in this order from an upstream side of a gas flow. The gas supply pipes 232a to 232h are made of, for example, a metallic material such as stainless steel or the like.

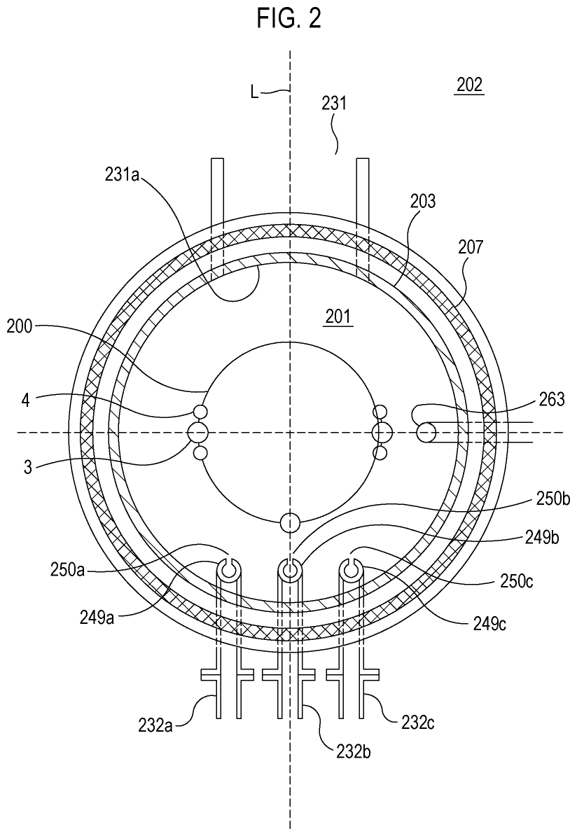

As shown in FIG. 2, the nozzles 249a to 249c are installed in a space that is formed in an annular shape in plan view between an inner wall of the reaction tube 203 and the wafers 200 and are installed to extend upward in an arrangement direction of the wafers 200 along a lower portion to an upper portion of the inner wall of the reaction tube 203. Here, the arrangement direction of the wafers 200 is a Z-axis direction. In other words, each of the nozzles 249a to 249c is installed at a region horizontally surrounding a wafer arrangement region at a lateral side of the wafer arrangement region, in which the wafers 200 are arranged, so as to extend along the wafer arrangement region. In plan view, the nozzle 249b is disposed so as to face an exhaust port 231a to be described below in a straight line with centers of the wafers 200 loaded into the process chamber 201 placed in between. The nozzles 249a and 249c are disposed such that a straight line L passing through the nozzle 249b and a center of the exhaust port 231a is interposed between both sides along the inner wall of the reaction tube 203 (an outer periphery of the wafers 200). The straight line L is also the straight line that passes through the nozzle 249b and the center of the wafers 200. That is, it can be said that the nozzle 249c is installed at an opposite side of the nozzle 249a with the straight line L interposed therebetween. The nozzles 249a and 249c are disposed line-symmetrically with the straight line L as an axis of symmetry. Gas supply holes 250a to 250c for supplying gases are installed in side surfaces of the nozzles 249a to 249c, respectively. Each of the gas supply holes 250a to 250c is open so as to face the exhaust port 231a when viewed in plan, which enables supply of gases toward the wafers 200. The gas supply holes 250a to 250c are installed along the lower portion to the upper portion of the reaction tube 203.

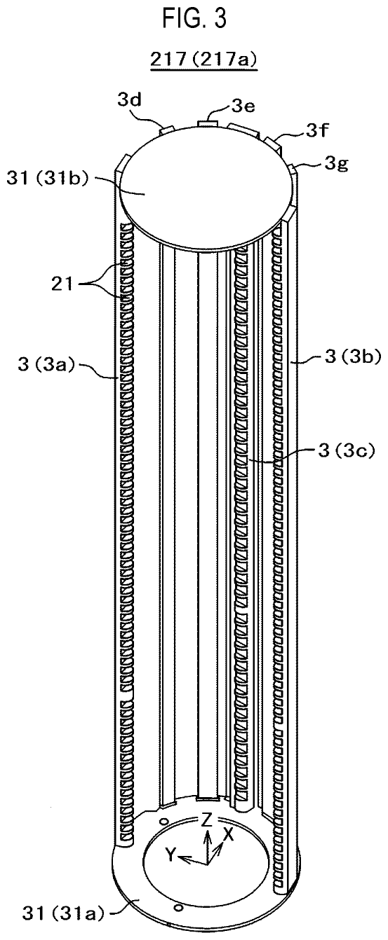

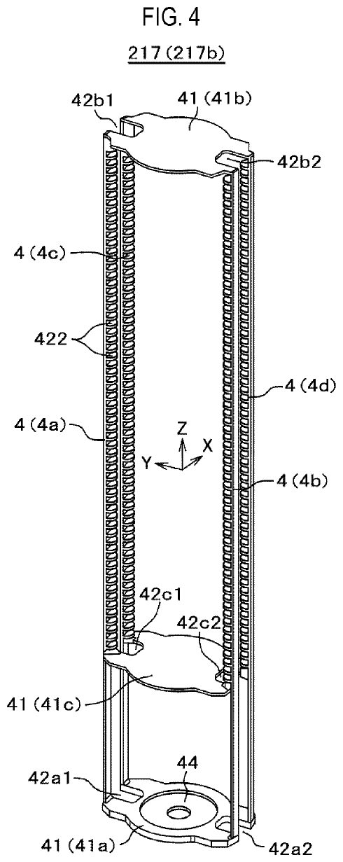

A plurality of first support columns 3 of a first boat 217a serving as a main boat and a plurality of second support columns 4 of a second boat 217b serving as a sub boat, which will be described with reference to FIGS. 3 and 4, are shown on the outer periphery of the wafers 200. The first support columns 3 may be referred to as fixed support columns, and the second support columns 4 may be referred to as movable support columns.

An etching gas is supplied from the gas supply pipe 232a into the process chamber 201 via the MFC 241a, the valve 243a, and the nozzle 249a. As the etching gas, for example, a fluorine (F)-containing gas may be used.

A reducing gas is supplied from the gas supply pipe 232b into the process chamber 201 via the MFC 241b, the valve 243b, and the nozzle 249b. As the reducing gas, for example, a hydrogen (H)-containing gas may be used.

A second processing gas serving as a precursor gas is supplied from the gas supply pipe 232c into the process chamber 201 via the MFC 241c, the valve 243c, and the nozzle 249c. As the second processing gas, for example, a gas containing a Group 14 element such as germanium (Ge) may be used.

A first processing gas serving as a precursor gas is supplied from the gas supply pipe 232d into the process chamber 201 via the MFC 241d, the valve 243d, the gas supply pipe 232a, and the nozzle 249a. As the first processing gas, for example, a gas containing a Group 14 element such as silicon (Si) may be used.

A dopant gas is supplied from the gas supply pipe 232e into the process chamber 201 via the MFC 241e, the valve 243e, the gas supply pipe 232b, and the nozzle 249b.

An inert gas is supplied from the gas supply pipes 232f to 232h into the process chamber 201 through the MFCs 241f to 241h, the valves 243f to 243h, the gas supply pipes 232a to 232c, and the nozzles 249a to 249c. The inert gas acts as a purge gas, a carrier gas, a dilution gas, or the like.

A gas supply mechanism 248 is configured as follows. An etching gas supply system is mainly constituted by the gas supply pipe 232a, the MFC 241a, and the valve 243a. A reducing gas supply system is mainly constituted by the gas supply pipe 232b, the MFC 241b, and the valve 243b. A second processing gas supply system (Ge-containing gas supply system) is mainly constituted by the gas supply pipe 232c, the MFC 241c, and the valve 243c. A first processing gas supply system (Si-containing gas supply system) is mainly constituted by the gas supply pipe 232d, the MFC 241d, and the valve 243d. A dopant gas supply system is mainly constituted by the gas supply pipe 232e, the MFC 241e, and the valve 243e. An inert gas supply system is mainly constituted by the gas supply pipes 232f to 232h, the MFCs 241f to 241h, and the valves 243f to 243h.

The exhaust port 231a for exhausting the atmosphere inside the process chamber 201 is installed at a lower portion of a side wall of the reaction tube 203. As shown in FIG. 2, the exhaust port 231a is installed at a position opposing (facing) the nozzles 249a to 249c (gas supply holes 250a to 250c) with the wafers 200 interposed therebetween in plan view. The exhaust port 231a may be installed to extend along the lower portion to the upper portion of the side wall of the reaction tube 203, that is, along the wafer arrangement region. An exhaust pipe 231 is connected to the exhaust port 231a. A vacuum pump 246 serving as a vacuum exhauster is connected to the exhaust pipe 231 via a pressure sensor 245 serving as a pressure detector (pressure detection part) for detecting a pressure inside the process chamber 201 and an automatic pressure controller (APC) valve 244 serving as a pressure regulator (pressure regulation part). The APC valve 244 is configured to be capable of performing or stopping vacuum exhaustion inside the process chamber 201 by being opened or closed while the vacuum pump 246 is in operation. The APC valve 244 is further configured to be capable of regulating the pressure inside the process chamber 201 by adjusting a degree of valve opening based on pressure information detected by the pressure sensor 245 while the vacuum pump 246 is in operation. An exhaust system is mainly constituted by the exhaust pipe 231, the APC valve 244 and the pressure sensor 245. The vacuum pump 246 may be included in the exhaust system.

A seal cap 219 serving as a furnace opening lid configured to be capable of airtightly sealing a lower end opening of the manifold 209 is installed below the manifold 209. The seal cap 219 is made of a metallic material such as, for example, stainless steel or the like, and is formed in a disc shape. An O-ring 220b serving as a seal that comes into contact with a lower end of the manifold 209 is installed on an upper surface of the seal cap 219. A rotator 267 serving as a rotation device for rotating a boat 217 (first boat 217a and second boat 217b) to be described later is installed below the seal cap 219. A rotary shaft 255 of the rotator 267 passes through the seal cap 219 and is connected to the boat 217. The rotator 267 is configured to rotate the wafers 200 by rotating the boat 217. The rotator 267 and the seal cap 219 are configured to be raised or lowered in a vertical direction by a boat elevator 115 which is an elevator arm serving as an elevating mechanism installed outside the reaction tube 203. That is, the boat elevator 115 as an elevator arm can drive the rotator 267 and the lid (seal cap 219) up or down. The boat elevator 115 is configured as a transfer apparatus (transfer mechanism) that loads or unloads (transfers) the wafers 200 into or out of the process chamber 201 by raising or lowering the seal cap 219.

A driver 268 serving as a drive mechanism is installed below the seal cap 219. An electromagnetic valve 51 is installed below the driver 268. Operations of the driver 268 are controlled by controlling the electromagnetic valve 51. The driver 268 is used to simultaneously raise or lower a plurality of wafers 200 in the boat 217 during a film formation process in the process chamber 201. That is, the driver 268 moves a second boat 217b (described later) relative to a first boat 217a in both directions (upward and downward) along the Z-axis. This allows the plurality of wafers 200 to be transferred from the first boat 217a to the second boat 217b, or to be returned from the second boat 217b to the first boat 217a.

Below the manifold 209, a shutter 219s is installed serving as a furnace opening lid capable of airtightly sealing the lower end opening of the manifold 209 in a state in which the seal cap 219 is lowered and the boat 217 is unloaded from the process chamber 201. The shutter 219s is made of a metallic material such as stainless steel or the like and is formed in a disc shape. An O-ring 220c serving as a seal that comes into contact with the lower end of the manifold 209 is installed on an upper surface of the shutter 219s. An opening/closing operation (raising/lowering operation, rotating operation, and the like) of the shutter 219s is controlled by a shutter opening/closing mechanism 115s.

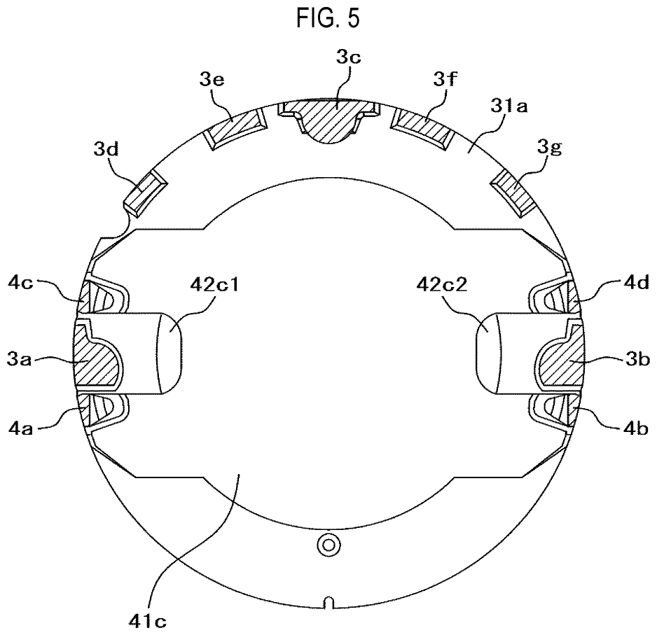

The boat 217 serving as a substrate holder includes a first boat 217a shown in FIG. 3 and a second boat 217b shown in FIG. 4, and the first boat 217a and the second boat 217b are combined together. FIG. 5 shows an example of a horizontal sectional view of the first boat 217a and the second boat 217b combined together.

The first boat 217a includes a plurality of first support portions (first support grooves) 21 configured so as to support a plurality of wafers 200, for example, 25 to 200 wafers 200 in a horizontal posture and in multiple stages while vertically arranging the wafers 200 with the centers of the wafers 200 aligned with each other, that is, so as to arrange the wafers 200 at intervals. The first boat 217a includes at least one first support portion 21 for each of the plurality of substrates (wafers), that is, for one substrate (wafer). The first boat 217a is made of a heat-resistant material such as, for example, quartz or SiC. As shown in FIG. 1, heat insulating plates 218 made of a heat-resistant material such as, for example, quartz or SiC, are supported in multiple stages at a lower portion of the first boat 217a.

As shown in FIG. 3, the first boat 217a includes a plurality of first support columns 3 that are extending in a direction (the direction of the Z-axis) substantially perpendicular to the wafers 200 and are each installed with first support portions 21, and a first coupler 31 configured to fix the plurality of first support columns 3 to one another. In this example, three first support columns 3a, 3b, and 3c are installed as the plurality of first support columns 3. The first coupler 31 includes a first bottom plate 31a that fixes the plurality of first support columns 3 to one another near lower ends of the plurality of first support columns 3 and a first top plate 31b that fixes the plurality of first support columns 3 to one another near upper ends of the plurality of first support columns 3. In other words, the first boat 217a holds a plurality of wafers 200 arranged along a predetermined axis (Z-axis). The first boat 217a also includes a plurality of first support columns 3 (3a, 3b and 3c) that extend in the direction of the predetermined axis (Z-axis) and support the plurality of wafers 200 from an outer peripheral side. Each of the plurality of first support columns 3a, 3b and 3c is provided with a plurality of first support portions 21. The first boat 217a is accommodated inside a process container (process chamber 201), and the plurality of wafers 200 mounted on the first boat 217a are processed inside the process container (process chamber 201).

In this example, as shown in FIGS. 3 and 5, a plurality of sub support columns 3d, 3e, 3f and 3g are further installed between the first bottom plate 31a and the first top plate 31b. The sub support columns 3d and 3e are installed between the first support column 3a and the first support column 3c, and the sub support columns 3f and 3g are installed between the first support column 3c and the first support column 3b. In this example, the sub support columns 3d, 3e, 3f and 3g are configured so that the first support portions 21 are not installed on the sub support columns 3d, 3e, 3f and 3g.

The second boat 217b includes a plurality of second support portions (second support grooves) 422 configured so as to support a plurality of wafers 200, for example, to 200 wafers 200 in a horizontal posture and in multiple stages while vertically arranging the wafers 200 with the centers of the wafers 200 aligned with each other, that is, so as to arrange the wafers 200 at intervals. The second boat 217b is installed so as to be movable in the direction of the axis (Z-axis) relative to the first boat 217a. That is, the plurality of second support portions 422 are installed so as to be movable in an up-down direction (the direction of the Z-axis) relative to the first boat 217a. The second boat 217b is made of a heat-resistant material such as quartz or SiC.

As shown in FIG. 4, the second boat 217b includes a plurality of second support columns 4 that are extending in a direction (the direction of the Z-axis) substantially perpendicular to the wafers 200 and are each installed with second support portions 422, and a second coupler 41 configured to fix the plurality of second support columns 4 to one another. In this example, four second support columns 4a, 4b, 4c and 4d are installed as the plurality of second support columns 4. The second coupler 41 includes a second bottom plate 41a that fixes the plurality of second support columns 4 to one another near lower ends of the plurality of second support columns 4, a second top plate 41b that fixes the plurality of second support columns 4 to one another near upper ends of the plurality of second support columns 4, and an intermediate plate 41c that fixes the plurality of second support columns 4 to one another near intermediate portions of the plurality of second support columns 4 (portions between the upper and lower ends). In other words, the second boat 217b includes a plurality of second support columns 4 (4a, 4b, 4c and 4d) that extend in the direction of the axis (Z-axis) and support the plurality of wafers 200 from the outer peripheral side. The second boat 217b also includes a plurality of second couplers 41 (41a, 41b and 41c) that couple the plurality of second support columns 4a, 4b, 4c and 4d to one another. The plurality of second couplers 41 are plate-shaped and extend in an X-axis direction and a Y-axis direction, which are perpendicular to the Z-axis direction. The plurality of second couplers 41 are rigidly joined to the plurality of second support columns 4a, 4b, 4c and 4d. As used herein, the term “rigidly joined” means that columns (here, the second support columns 4) and beams (here, the second couplers 41) are joined by welding so as to be integrated.

Each of the plurality of second support columns 4 (4a, 4b, 4c and 4d) is installed with a plurality of second support portions 422. The second top plate 41b and the second bottom plate 41a of the second boat 217b are configured to be able to be fitted between the first top plate 31b and the first bottom plate 31a of the first boat 217a. In a state in which the plurality of second support columns 4 can be separated from and contacted by the driver 268, the plurality of second support columns 4 are disposed to be rotatable together with the first boat 217a around the outer periphery of the wafers 200 supported by the first boat 217a, as shown in FIG. 2, in a state in which they can be separated from and contacted by the driver 268.

The second bottom plate 41a is configured as a plate formed in a shape that allows the second bottom plate 41a to be stably placed on the first bottom plate 31a. As shown in FIG. 4, a center of gravity of the second boat 217b is on the Z axis, and the second bottom plate 41a, which is one of the plurality of second couplers 41, includes a support portion 44 that receives a drive force from the driver 268 on the Z axis. As shown in FIGS. 4 and 5, first cutouts 42a1, 42b1 and 42c1, through which the first support columns 3a are inserted, are installed at one side of each of the second bottom plate 41a, the second top plate 41b, and the intermediate plate 41c, respectively. In addition, second cutouts 42a2, 42b2, and 42c2, through which the first support columns 3b are inserted, are installed at the other side of each of the second bottom plate 41a, the second top plate 41b, and the intermediate plate 41c. In other words, each of the plurality of second couplers 41 (41a, 41b and 41c) includes two cutouts (the first cutouts 42a1, 42b1 and 42c1 and the second cutouts 42a2, 42b2 and 42c2) corresponding to two first support columns (3a and 3b) among the plurality of first support columns (3a, 3b and 3c).

The driver 268 is configured to relatively lift the second support portions 422 upward in the Z-axis direction to float the wafers 200 from at least one first support portion 21. Specifically, in the configuration in which the first boat 217a and the second boat 217b are combined, the second boat 217b is configured to be movable up and down in the Z-axis direction within a range in which upper and lower ends of the second boat 217b are restrained relative to the first boat 217a. During the film formation process, the driver 268 moves the second boat 217b upward in the Z-axis direction within the range in which the upper and lower ends of the second boat 217b are restrained relative to the first boat 217a, thereby lifting the plurality of wafers 200 at once. Then, the driver 268 moves the second boat 217b downward in the Z-axis direction within a range in which its upper and lower ends are restrained relative to the first boat 217a, thereby lowering the plurality of wafers 200 at once. In other words, during the film formation process, the driver 268 moves the second boat 217b relatively in both directions along the axis (Z axis), thereby controlling the plurality of wafers 200 to be transferred from the first boat 217a to the second boat 217b and then to be returned from the second boat 217b to the first boat 217a.

In FIGS. 3 to 5, the X-axis indicates a front-rear direction, the Y-axis indicates a left-right direction, and the Z-axis indicates the up-down direction. As shown in FIGS. 3 to 5, when the direction perpendicular to the Z-axis, in which the plurality of wafers 200 can be inserted into the first boat 217a (a front side of the X-axis), is defined as front, the following configuration is adopted.

1) The first boat 217a is configured so that the wafers 200 can be inserted from the front.

2) Among the plurality of first support columns (3a, 3b and 3c), two first support columns (3a and 3b) are disposed at both sides (left and right sides) of the center of the wafers 200 (corresponding to the position of the Z axis in FIG. 4).

3) The plurality of second support columns 4 (4a, 4b, 4c and 4d) are disposed so that the two first support columns (3a and 3b) are sandwiched between the plurality of second support columns 4 in the front-rear direction.

4) The plurality of second support columns 4 (4a, 4b, 4c and 4d) are configured to be symmetrical in the front-rear and left-right directions or rotationally symmetrical with respect to the center of gravity of the wafers 200 (corresponding to the position of the Z axis in FIG. 4).

Depths of the cutouts (the first cutouts 42a1, 42b1 and 42c1 and the second cutouts 42a2, 42b2 and 42c2) are set as follows. When assembling the second boat 217b into the first boat 217a, for example, as shown in FIG. 4, the first support column 3a is first inserted deep into the first cutouts 42a1, 42b1 and 42c1. Thus, the second support column 4d passes to the left of the first support column 3b, thereby causing the first support column 3b to be disposed within the second cutouts 42a2, 42b2 and 42c2. In this case, a distance between the first support column 3a and the second support column 4d may be shorter than a distance (shortest distance) between an inner side of the first support column 3a and an inner side of the first support column 3b. Taking this into consideration, the depths of the first cutouts 42a1, 42b1 and 42c1 and the second cutouts 42a2, 42b2 and 42c2 are set.

That is, a cutout depth of at least one (first cutout or second cutout) selected from the group of the cutouts (the first cutouts 42a1, 42b1 and 42c1 and the second cutouts 42a2, 42b2 and 42c2) is set so that, by inserting one (3a or 3b) of the two first support columns (3a and 3b) into the at least one cutout (the first cutout or the second cutout), the maximum distance between one (3a or 3b) of the two first support columns (3a and 3b) and one second support column (4d or 4c) disposed behind the other cutout (the second cutout or the first cutout) is shorter than the shortest distance between one (3a or 3b) of the two first support columns and the other (3b or 3a) of the two first support columns corresponding to the other cutout (the second cutout or the first cutout).

In order to avoid inhibition of a side flow of a gas, sufficient gaps may be ensured between the support columns and a length of claws (depth of the grooves in the first support portions 21 and the second support portions 221) may be set. This allows the gas from the nozzles 249a to 249c to properly reach the wafers 200 without being inhibited by the support columns, which makes it possible to shorten film formation time and improve film quality. For example, a case is considered in which a diameter of the wafers 200 to be processed is, for example, 300 mm, and a diameter of the first boat 217a is, for example, approximately 340 mm. In this case, the gap between the first support column 3a and the second support column 4a and the gap between the first support column 3a and the second support column 4c may be set to, for example, about 20 mm, and a width of the first support column 3a may be set to, for example, about 40 mm. Similarly, the gap between the first support column 3b and the second support column 4b and the gap between the first support column 3b and the second support column 4d may be set to, for example, about 20 mm, and a width of the first support column 3b may be set to, for example, about 40 mm. Regarding the length of the claws (depth of the grooves of the first support portions 21, and depth of the grooves of the second support portions 221), when the width of the first support columns 3a, 3b and 3c is, for example, about 35 mm, the depth of the grooves (the length of the claws) may be set to, for example, about 19 mm.

When forming a thick film on a wafer, depending on a thickness of the film, the film may also be deposited on the substrate support (boat) itself, causing adhesion between the substrate support and the wafer, resulting in particle generation. In order to reduce this particle generation, it is conceivable to adopt a method of first unloading the substrate support from the process furnace after a film with a certain film thickness is formed, lifting the wafers one by one in a transfer chamber using a trasferrer and returning the wafers to their original positions, reloading the substrate support into the process furnace, and forming a thick film on each of the wafers. However, this method may increase film formation time, deteriorate film quality due to oxidation, and cause uneven thermal history. On the other hand, by lifting the wafers 200 within the process chamber 201 as in the present embodiment, it is possible to shorten film formation time and improve film quality. Further, since the plurality of wafers 200 are simultaneously lifted under a reduced pressure inside the process furnace 202 (process chamber 201), throughput is dramatically improved. Moreover, since the substrate support is not moved into the transfer chamber, oxidation in the transfer chamber is suppressed, and the thermal history of the wafers 200 associated with tweezer picking-up is reduced. This improves the film quality. The transfer chamber is in an air or a nitrogen (N) atmosphere with an oxygen (O) concentration of 20 ppm or less. In addition, since back surfaces (rear surfaces) of the wafers 200 are exposed in the process chamber 201, films are formed on both front surfaces and the opposing back surfaces (rear surfaces) of the wafers 200, which makes it possible to prevent the wafers 200 from warping.

A temperature sensor 263 serving as a temperature detector is installed inside the reaction tube 203. By adjusting a state of supplying electric power to the heater 207 based on temperature information detected by the temperature sensor 263, a temperature inside the process chamber 201 falls within a desired temperature distribution. The temperature sensor 263 is installed along the inner wall of the reaction tube 203.

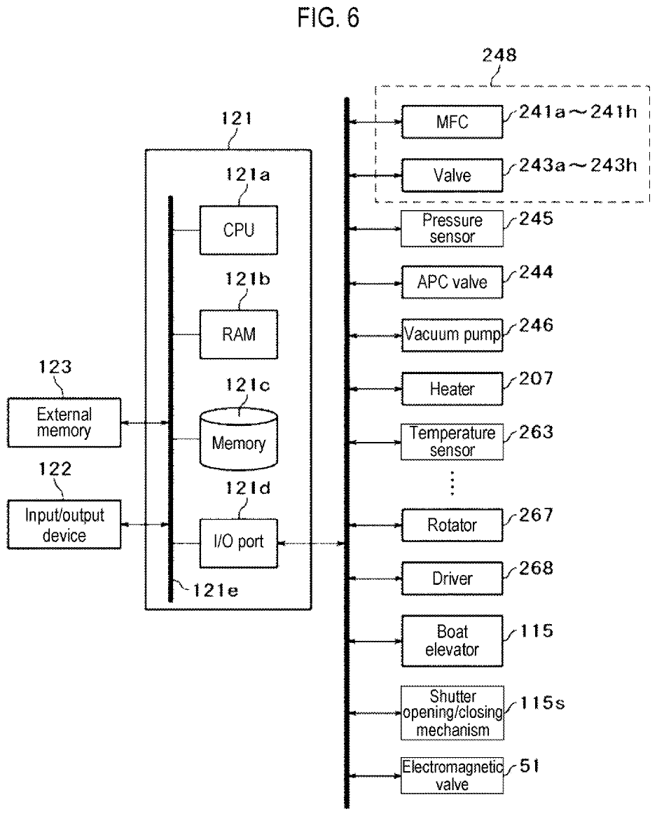

As shown in FIG. 6, the controller 121 serving as a control part (control means or unit) is constituted as a computer including a central processing unit (CPU) 121a, a random access memory (RAM) 121b, a memory 121c and an input/output (I/O) port 121d. The RAM 121b, the memory 121c and the I/O port 121d are configured to exchange data with the CPU 121a via an internal bus 121e. An input/output device 122 constituted as, for example, a touch panel or the like is connected to the controller 121. In addition, an external memory 123 can be connected to the controller 121.

The memory 121c is constituted by, for example, a flash memory, a hard disk drive (HDD), a solid state drive (SSD), or the like. The memory 121c stores, in a readable manner, a control program that controls operations of the substrate processing apparatus, a process recipe in which procedures and conditions of substrate processing to be described later are written, or the like. The process recipe is a combination that causes, by the controller 121, the substrate processing apparatus to execute respective procedures in a substrate processing process to be described later, so as to obtain an expected result. The process recipe is also referred to as a “program.” Further, the process recipe is also simply referred to as a “recipe.” When the term “program” is used herein, this may mean a case of including the recipe, a case of including the control program, or a case of including both the recipe and the control program. The RAM 121b is constituted as a memory area (work area) in which programs, data and the like read by the CPU 121a are temporarily held.

The I/O port 121d is connected to the MFCs 241a to 241h, the valves 243a to 243h, the pressure sensor 245, the APC valve 244, the vacuum pump 246, the temperature sensor 263, the heater 207, the rotator 267, the boat elevator 115, the shutter opening/closing mechanism 115s, the electromagnetic valve 51, and the like.

The CPU 121a is configured to be capable of reading and executing the control program from the memory 121c and of reading the recipe from the memory 121c in response to an input of an operation command from the input/output device 122 or the like. According to contents of the read recipe, the CPU 121a is configured to be capable of controlling flow rate regulating operations for various substances (various gases) by the MFCs 241a to 241h, the opening/closing operations of the valves 243a to 243h, the opening/closing operation of the APC valve 244, the pressure regulation operation by the APC valve 244 based on the pressure sensor 245, the actuating and stopping of the vacuum pump 246, the temperature regulating operation of the heater 207 based on the temperature sensor 263, the rotation operation and rotational speed adjustment operation of the boat 217 by the rotator 267, the raising and lowering operation of the second boat 217b by the driver 268, the raising and lowering operation of the boat 217 by the boat elevator 115, the opening/closing operation of the shutter 219s by the shutter opening/closing mechanism 115s, the opening/closing operation of the electromagnetic valve 51, and the like.

The controller 121 may be configured by installing, in the computer, the above-described program stored in an external memory 123. The external memory 123 includes, for example, a magnetic disk such as a HDD, an optical disk such as a CD, a magneto-optical disk such as an MO, a semiconductor memory such as a USB memory, an SSD. The memory 121c and the external memory 123 are constituted as a computer-readable recording medium. Hereinafter, the memory 121c and the external memory 123 are collectively and simply referred to as a “recording medium.” As used herein, the term “recording medium” may indicate a case of including the memory 121c, a case of including the external memory 123, or a case of including both the memory 121c and the external memory 123. The programs may be provided to the computer by using communication means such as the Internet or a dedicated line, instead of using the external memory 123.

The controller 121 is configured to control: a process a (or procedure a) of accommodating the first boat 217a, which holds the plurality of wafers 200 arranged along a predetermined axis (Z-axis), into the process container (203 or 209); a process b (or procedure b) of processing the plurality of wafers 200 in the process container while rotating the first boat 217a by the rotator 267 including the rotary shaft 255 which supports the first boat 217a so as to be rotatable about the axis (Z-axis); a process c (or procedure c) of lifting the second boat 217b upward and delivering the plurality of wafers 200 from the first boat 217a to the second boat 217b by the driver 268 which is capable of driving the second boat 217b in the direction of the axis (Z-axis) and separating the plurality of wafers 200 from the first boat 217a; and a process d (or procedure d) of, after the process c, driving the second boat 217b in the direction of the axis (Z-axis), lowering the second boat 217b downward by the driver 268, and returning the plurality of wafers 200 from the second boat 217b to the first boat 217a. The controller 121 is configured to control the rotator 267 to stop the rotation of the boats (217a and 217b) during the processes c and d.

### (2) Substrate Processing Process

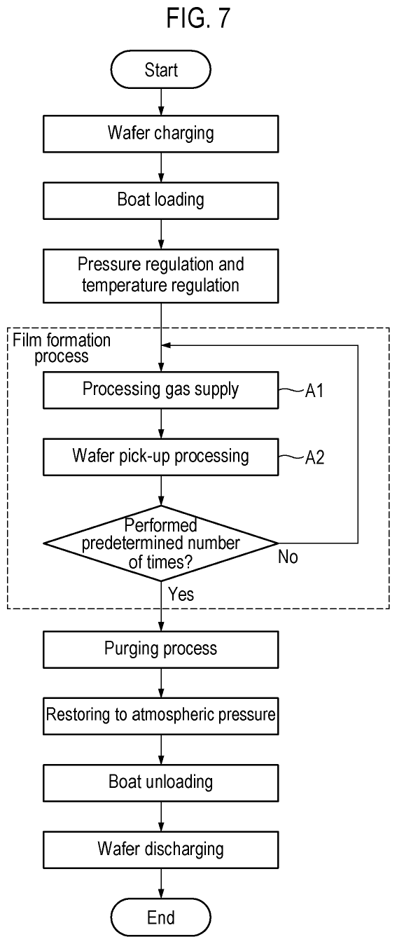

A method of processing a substrate as one process (method) of manufacturing a semiconductor device by using the above-described substrate processing apparatus, that is, an example of a processing sequence for growing a film on a surface of a wafer 200 serving as a substrate, will be described with reference to FIG. 7. In the following description, operations of each component of the substrate processing apparatus is controlled by the controller 121.

The term “wafer” used in the present specification may refer to a wafer itself or a stack of a wafer and a predetermined layer or film formed on the surface of the wafer. The phrase “a surface of a wafer” used herein may refer to a surface of the wafer itself or a surface of a predetermined layer or the like formed on the wafer. The expression “a predetermined layer is formed on a wafer” used herein may mean that a predetermined layer is directly formed on a surface of a wafer itself or that a predetermined layer is formed on a layer or the like formed on a wafer. The term “substrate” used in the present specification may be synonymous with the term “wafer.” In the present specification, the expression of a numerical range such as “1 to 2,000 Pa” means that a lower limit and an upper limit are included in the range. Therefore, for example, “1 to 2,000 Pa” means “1 Pa or more and 2,000 Pa or less.” The same applies to other numerical ranges. Further, when a supply flow rate includes 0 slm, 0 slm means that a substance (gas) is not supplied. This also applies to the following description. In the present specification, a processing temperature refers to a temperature of the wafer 200 or a temperature inside the process chamber 201, and a processing pressure refers to a pressure inside the process chamber 201. In addition, a processing time refers to a time during which a process continues. These also apply to the following description.

### Wafer Charging and Boat Loading

After the plurality of wafers 200 is charged to the boat 217 (wafer charging), the shutter 219s is moved by the shutter opening/closing mechanism 115s to open the lower end opening of the manifold 209 (shutter opening). Thereafter, as shown in FIG. 1, the boat 217 supporting the plurality of wafers 200 is lifted by the boat elevator 115 and loaded into the process chamber 201 (boat loading). In this state, the seal cap 219 seals the lower end of the manifold 209 via the O-ring 220b. Thus, the wafers 200 are loaded into the process chamber 201.

### Pressure Regulation and Temperature Regulation

After the boat loading is completed, an inside of the process chamber 201, that is, a space in which the wafers 200 exist, is exhausted (depressurized) by the vacuum pump 246 so that the pressure inside the process chamber 201 reaches a desired pressure (degree of vacuum). At this time, the pressure inside the process chamber 201 is measured by the pressure sensor 245, and the APC valve 244 is feedback-controlled based on the measured pressure information. Further, the wafers 200 in the process chamber 201 are heated by the heater 207 so that the wafers 200 reach a desired processing temperature (first temperature). At this time, the state of supplying electric power to the heater 207 is feedback-controlled based on the temperature information detected by the temperature sensor 263 so that the temperature inside the process chamber 201 falls within a desired temperature distribution. Moreover, the rotation of the wafers 200 by the rotator 267 is started. The exhaustion of the process chamber 201 and the heating and rotation of the wafers 200 are continuously performed at least until the wafers 200 are completely processed.

### Film Formation Process (A1 and A2)

### Step A1: Processing Gas Supply Process

In step A1, in a state in which the wafers 200 are heated to a predetermined temperature, at least one selected from the group of a first processing gas and a second processing gas is supplied to the wafers 200 to perform a film formation process to grow a film on the surfaces of the wafers 200.

When depositing a SiGe film, the second processing gas is allowed to flow through the gas supply pipe 232c. A flow rate of the second processing gas is regulated by the MFC 241c. The second processing gas is supplied into the process chamber 201 via the gas supply pipe 232c and the nozzle 249c. In this state, the valve 243d is opened to allow the first processing gas to flow into the gas supply pipe 232d. A flow rate of the first processing gas is regulated by the MFC 241d. The first processing gas is supplied into the process chamber 201 via the gas supply pipe 232a and the nozzle 249a, and is exhausted together with the second processing gas from the exhaust port 231a. At this time, the first processing gas and the second processing gas are supplied to the wafers 200 from the lateral side of the wafers 200. At this time, the valves 243f to 243h may be opened to supply an inert gas into the process chamber 201 via each of the nozzles 249a to 249c.

Processing conditions in step A1 are exemplified as follows:
Processing temperature (predetermined temperature): 500 to 650 degrees C., specifically 550 to 600 degrees C.
Processing pressure: 4 to 200 Pa, specifically 1 to 120 Pa
First processing gas supply flow rate: 0.1 to 5 slm, specifically 0.2 to 3 slm
Second processing gas supply flow rate: 0.1 to 5 slm, specifically 0.2 to 310 slm
Inert gas supply flow rate (per gas supply pipe): 0 to 20 slm, specifically 0.1 to 10 slm
Gas supply time: 20 minutes to 60 hours, specifically 30 to 360 minutes

By supplying the first processing gas and the second processing gas to the wafers 200 under the above-described processing conditions, an epitaxial film, for example, an epitaxial SiGe film containing a predetermined element, can be formed on the surfaces of the wafers 200. By supplying the first processing gas as a precursor gas, a Si film can be formed.

After step A1 is completed, the valves 243a and 243c are closed to stop the supply of the first processing gas and the second processing gas into the process chamber 201.

### Step A2: Wafer Pick-up Processing

After step A1, the driver 268 moves the second boat 217b relatively upward, simultaneously lifting the plurality of wafers 200 from the first boat 217a. After a certain period of time passes, the driver 268 moves the second boat 217b relatively downward, simultaneously disposing the plurality of wafers 200 into the first boat 217a.

### Performing Predetermined Number of Times

A cycle of alternately performing steps A1 and A2 described above is performed a predetermined number of times (n times where n is an integer greater than or equal to 1).

### Purging Process

After the film formation process is completed, an inert gas serving as a purge gas is supplied into the process chamber 201 from each of the nozzles 249a to 249c and is exhausted through the exhaust port 231a. As a result, the inside of the process chamber 201 is purged so that gases, by-products, and the like remaining inside the process chamber 201 are removed from the inside of the process chamber 201 (after-purging). Thereafter, the atmosphere inside the process chamber 201 is substituted with an inert gas (inert gas substitution), and the pressure inside the process chamber 201 is returned to the atmospheric pressure (restoring to atmospheric pressure).

### Boat Unloading and Wafer Discharging

Thereafter, the seal cap 219 is lowered by the boat elevator 115, and the lower end of the manifold 209 is opened. Then, the processed wafers 200 are unloaded from the lower end of the manifold 209 to an outside of the reaction tube 203 while being supported by the boat 217 (boat unloading). After the boat is unloaded, the shutter 219s is moved and the lower end opening of the manifold 209 is sealed by the shutter 219s via the O-ring 220c (shutter closing). The processed wafers 200 are discharged from the boat 217 after they are unloaded to the outside of the reaction tube 203 (wafer discharging).

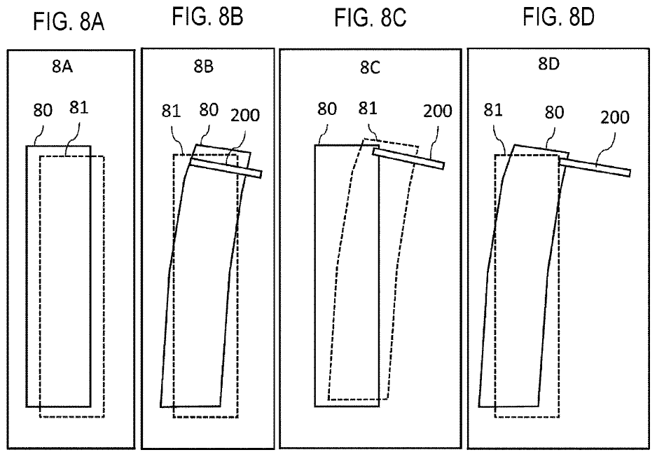

Next, misalignment of the wafers in a comparative boat will be described with reference to FIGS. 8A to 8D. FIG. 8A is a conceptual side view of a main boat 80 and a sub boat 81 when no wafers 200 are mounted, FIG. 8B is a conceptual side view of the main boat 80, the sub boat 81, and the wafer 200 during film formation, FIG. 8C is a conceptual side view of the main boat 80, the sub boat 81, and the wafer 200 during pick-up, and FIG. 8D is a conceptual side view of the main boat 80, the sub boat 81, and the wafer 200 during film formation after pick-up.

Sagging of the boats (80 and 81) occurs due to asymmetrical arrangement of the support columns installed at the main boat 80 and the sub boat 81.

In FIG. 8A, since no wafer 200 is mounted, no sagging occurs in the main boat 80 and the sub boat 81.

In FIG. 8B, the main boat 80 sags forward during film formation, causing the wafer 200 to sag slightly in the main boat 80. No sagging occurs in the sub boat 81.

In FIG. 8C, the wafer 200 that sagged during film formation is picked up by the sub boat 81 that is sagging forward. Therefore, the wafer 200 also sags on the sub boat 81.

In FIG. 8D, the wafer 200 sagging due to pick-up is placed on the main boat 80 that is sagging forward. Therefore, the misalignment of the wafer 200 is accumulated.

According to the study conducted by the disclosers of the present disclosure, the following was found.
1) It is known that a direction of horizontal displacement due to bending of each support column is such that each support column bends and deflects in a direction in which a cross section of the support column is thin (in a radial direction of the boat).
2) The displacements of the first boat (217a) and the second boat (217b) may be set to cancel each other out. That is, the first boat (217a) may be designed to bend forward, and the second boats (217b and 9b) may be designed to bend rearward. When an amount of elastic deformation of rear columns (4c, 4d, 7c and 7d) is set to be larger than that of the front columns (4a, 4b, 7a and 7b) to be described in the second boats (217b and 9b), the second boats (217b and 9b) can be made to bend rearward.

Therefore, in order to prevent the wafers 200 from being misaligned, the first boat and the second boat of the present disclosure may be configured as follows.
1) In the second boat 217b, the second support columns 4 (4a, 4b, 4c and 4d) are configured to be symmetrical in the front-rear and left-right directions or rotationally symmetrical with respect to the center of gravity of the wafer 200 (corresponding to the position on the Z axis in FIG. 4). This makes it possible to reduce deflection of the second boat 217b.
2) The amount and the direction of elastic deformation of at least one selected from the group of the first boat 217a and the second boat 217b when supporting the plurality of wafers 200 are set so that substantially no displacement occurs in perpendicular directions (X-axis direction and Y-axis direction) with respect to the axis (Z-axis) of the plurality of wafers 200 after a cycle including the delivery and return of the plurality of wafers 200 is performed one or more times. Here, the elastic deformation refers to a deflection deformation caused by compression of at least one selected from the group of the plurality of first support columns 3 (3a, 3b and 3c) and the plurality of second support columns 4 (4a, 4b, 4c and 4d) in a longitudinal direction (Z-axis direction) thereof.
3) The arrangement and amount of elastic deformation of at least one selected from the group of the plurality of first support columns 3 (3a, 3b and 3c) and the plurality of second support columns 4 (4a, 4b, 4c and 4d) are set so that when supporting the plurality of wafers 200, substantially no displacement occurs in perpendicular directions (X-axis direction and Y-axis direction) compared to a state before supporting the plurality of wafers 200.
4) At least one selected from the group of the plurality of first support columns 3 (3a, 3b and 3c) and the plurality of second support columns 4 (4a, 4b, 4c and 4d) is elastically deformed such that the displacement in the direction of the axis (Z-axis) when supporting the plurality of wafers 200 substantially matches that of a state before the supporting.

This can reduce horizontal misalignment of the wafers 200 caused by the deflection of the first boat 217a and the second boat 217b when supporting the wafers 200.

### Modification 1

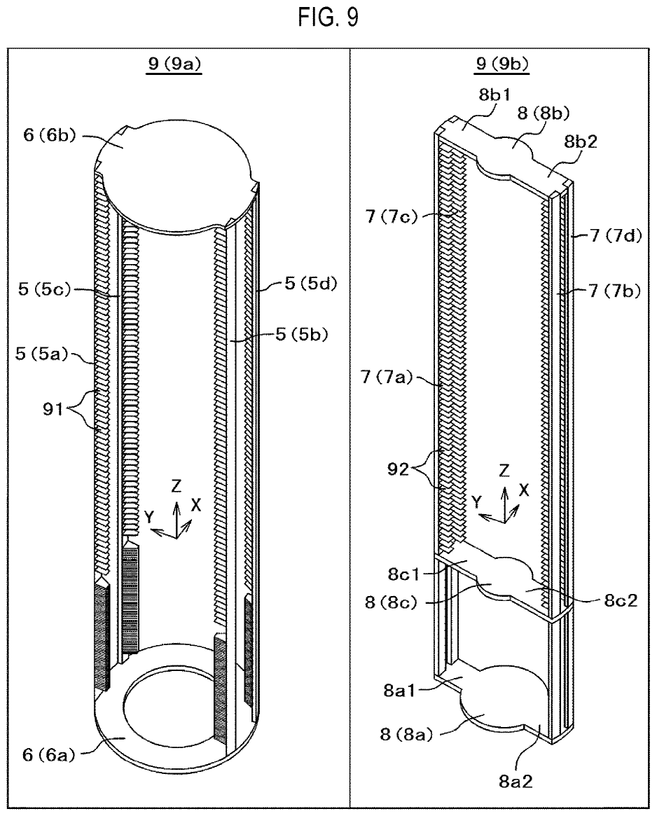

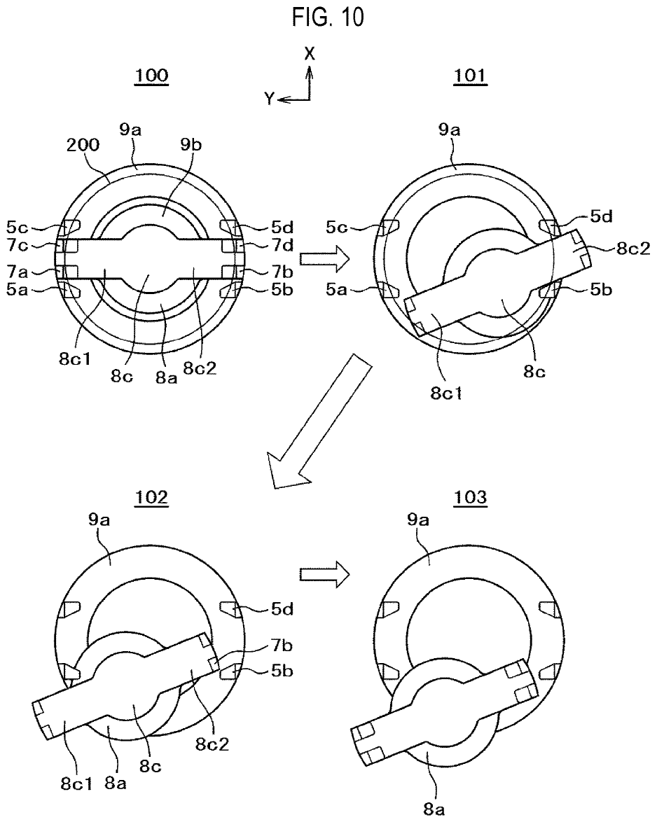

Next, a first boat and a second boat according to a modification will be described using FIGS. 9 and 10. As shown in FIG. 9, the boat 9 according to the present modification includes a first boat 9a and a second boat 9b. The first boat 9a is configured to be symmetrical in the front-rear and left-right directions, or rotationally symmetrical, with respect to the center of gravity of the wafer or a center of gravity of the first boat 9a. Similarly, the second boat 9b is configured to be symmetrical in the front-rear and left-right directions, or rotationally symmetrical, with respect to the center of gravity of the wafer or a center of gravity of the second boat 9b.

The first boat 9a is configured to hold a plurality of wafers 200 arranged along a predetermined axis (Z-axis), and includes a plurality of first support columns 5 (5a, 5b, 5c and 5d) that extend in the direction of the Z-axis and support the plurality of wafers 200 from the outer peripheral side. In this example, four first support columns 5a, 5b, 5c and 5d are installed. Each of the plurality of first support columns 5 includes a plurality of first support portions (first support grooves) 91 for supporting the wafers 200. The plurality of first support columns 5 are disposed to be symmetrical in the front-rear and left-right directions or rotationally symmetrical with respect to the center of gravity of the wafers 200 or the center of gravity of the first boat 9a.

The first boat 9a further includes a plurality of plate-shaped couplers 6 (bottom plate 6a and upper plate 6b) that extend in the X-axis direction and the Y-axis direction, which are perpendicular to the Z-axis direction, to couple the plurality of first support columns 5 to one another.

When the direction of the X-axis, which is perpendicular to the Z-axis and through which the plurality of wafers 200 can be inserted into the first boat 9a, is defined as the front, the first boat 9a is configured so that the wafers 200 can be inserted from the front. Two first support columns (5a and 5c) and two first support columns (5b and 5d) among the four first support columns 5a, 5b, 5c and 5d are disposed at both the left and right sides of the center of the wafers 200. In other words, two first support columns 5a and 5c are disposed at the left side, and two first support columns 5b and 5d are disposed at the right side.

The second boat 9b is configured to hold a plurality of wafers 200 arranged along a predetermined axis (Z-axis) and includes a plurality of second support columns 7 (7a, 7b, 7c and 7d) that extend in the direction of the Z-axis to support the plurality of wafers 200 from the outer peripheral side. In this example, four second support columns 7a, 7b, 7c and 7d are installed. Each of the plurality of second support columns 7 includes a plurality of second support portions (second support grooves) 92 for supporting the wafers 200. The plurality of second support columns 7 are disposed to be symmetrical in the front-rear and left-right directions or rotationally symmetrical with respect to the center of gravity of the wafers 200 or the center of gravity of the second boat 9b. Two second support columns (7a and 7c) and two second support columns (7b and 7d)) among the four second support columns 7a, 7b, 7c and 7d are disposed at both the left and right sides of the center of the wafers 200. That is, two second support columns 7a and 7c are disposed at the left side, and two second support columns 7b and 7d are disposed at the right side. In a case where the first boat 9a and the second boat 9b are combined, the two second support columns 7a and 7c are disposed so as to be sandwiched between the two first support columns 5a and 5c in the front-rear direction, and the two second support columns 7b and 7d are disposed so as to be sandwiched between the two first support columns 5b and 5d in the front-rear direction.

The second boat 9b includes a plurality of plate-shaped couplers 8 (a bottom plate 8a, an intermediate plate 8c, and an upper plate 8b) that extend in the X-axis direction and the Y-axis direction, which are perpendicular to the Z-axis direction, to couple the plurality of second support columns 7 to one another. The couplers 8 (the bottom plate 8a, the intermediate plate 8c, and the upper plate 8b) and the plurality of second support columns 7 are rigidly joined to one another.

Each of the plurality of plate-shaped couplers 8 (the bottom plate 8a, the intermediate plate 8c, and the upper plate 8b) includes arms (8a1, 8a2, 8b1, 8b2, 8c1 and 8c2) that extend in a radial direction (Y-axis direction) of the second boat 9b with a width narrower than a distance between the two first support columns ((a distance between 5a and 5c) and (a distance between 5b and 5d)). In other words, the width of the arms 8a1, 8b1 and 8c1 in the X-axis direction is narrower than the distance between the first support columns 5a and 5c in the X-axis direction. Thus, the arms 8a1, 8b1 and 8c1 are configured to be inserted between the first support columns 5a and 5c. Similarly, the width of the arms 8a2, 8b2 and 8c2 in the X-axis direction is narrower than the distance between the first support columns 5b and 5d in the X-axis direction. Thus, the arms 8a2, 8b2 and 8c2 are configured to be inserted between the first support columns 5b and 5d. In other words, in the case where the first boat 9a and the second boat 9b are combined, the plurality of second support columns are disposed to be sandwiched between two first support columns in the front-rear direction on each of the left and right sides. That is, the two second support columns 7a and 7c are disposed to be sandwiched between the two first support columns 5a and 5c in the front-rear direction. Similarly, the two second support columns 7b and 7d are disposed to be sandwiched between the two first support columns 5a and 5c in the front-rear direction.

In the case where the first boat 9a and the second boat 9b are combined, for example, the following procedure is taken.

11) First, the arms 8a1, 8b1 and 8c1 are inserted between the first support columns 5a and 5c. At this time, a longitudinal direction of the plurality of couplers 8 of the second boat 9b is tilted from the Y-axis direction when viewed from above.

21) Then, the arms 8a2, 8b2 and 8c2 are moved in the X-axis direction to face a space between the first support columns 5b and 5d. At this time, the longitudinal direction of the plurality of couplers 8 of the second boat 9b is aligned with the Y-axis direction when viewed from above.

31) Then, the arms 8a2, 8b2 and 8c2 are inserted so that they are disposed between the first support columns 5b and 5d. In other words, the entire second boat 9b is moved to the right. At this time, the arms 8a1, 8b1 and 8c1 are disposed between the first support columns 5a and 5c.

41) Then, the bottom plate 8a of the second boat 9b is disposed at the bottom plate 6a of the first boat 9a, and the first boat 9a and the second boat 9b are combined.

In the above example, the arms 8a1, 8b1 and 8c1 are first inserted between the first support columns 5a and 5c. However, the present disclosure is not limited thereto. It is also possible to first insert the arms 8a2, 8b2 and 8c2 between the first support columns 5b and 5d. In this case, in the above-mentioned 11), 21), 31) and 41), the arms 8a1, 8b1 and 8c1 may be replaced with the arms 8a2, 8b2 and 8c2, the arms 8a2, 8b2 and 8c2 may be replaced with the arms 8a1, 8b1 and 8c1, the first support columns 5a and 5c may be replaced with the first support columns 5b and 5d, and the first support columns 5b and 5d may be replaced with the first support columns 5a and 5c.

FIG. 10 schematically shows a case where the second boat 9b is removed from the first boat 9a. In this example, the movement of the intermediate plate 8c will be described as a representative example. In the following description, the Y-axis direction is the left-right direction, and the X-axis direction is the front-rear direction. In the case where the second boat 9b is removed from the first boat 9a, as shown in FIG. 10, the operation is performed in the order of state 100, state 101, state 102, and state 103.

### State 100

State 100 is an initial state in which the first boat 9a is combined with the second boat 9b. The arm 8c1 of the intermediate plate 8c is disposed between the first support columns 5a and 5c, and the arm 8c2 of the intermediate plate 8c is disposed between the first support columns 5b and 5d. The two second support columns 7a and 7c of the second boat 9b are disposed to be sandwiched between the two first support columns 5a and 5c of the first boat 9a in the front-rear direction. Similarly, the two second support columns 7b and 7d of the second boat 9b are disposed to be sandwiched between the two first support columns 5a and 5c of the first boat 9a in the front-rear direction.

### State 101

First, the second boat 9b is moved to the right, and the arm 8c2 is deeply inserted between the first support columns 5b and 5d. At this time, a left end of the arm 8c1 is moved away from a region between the first support columns 5a and 5c. The second boat 9b is then rotated to the left such that a left end of the arm 8c1 moves forward while avoiding contact between front and rear side surfaces of the arm 8c2 and the first support columns 5b and 5d, and between the left end of the arm 8c1 and the first support column 5a.

### State 102

Next, the second boat 9b is moved to a left front side such that a right end of the arm 8c2 is moved away from a region between the first support columns 5b and 5d while avoiding contact between a left rear side of the bottom plate 8a of the second boat 9b and the first support column 5a. At this time, when viewed from above, the second boat 9b is tilted at a predetermined angle with respect to the Y-axis. Further, the second support column 7b and the first support column 5b are spaced apart from each other.

### State 103

Next, while maintaining the predetermined angle and avoiding contact between the second support column 7b and the first support column 5b, the second boat 9b is moved forward and removed from the first boat 9a.

According to the present disclosure, one or more of the following effects may be obtained.

1) By setting strengths of the support columns of the first and second boats such that the horizontal displacements of the first and second boats due to the wafer load are suppressed or cancelled out, horizontal misalignment of the wafers due to pick-up operation can be prevented.

2) The first and second boats include no moving parts and are simply configured to come into contact with each other at bottoms thereof. This makes it possible to suppress particle generation and prevent wafers from being horizontally misaligned.

While the present disclosure is specifically described above based on the embodiments, the present disclosure is not limited to the above-described embodiments and various modifications may be made. The present disclosure is not limited to a vertical substrate processing apparatus, and may also be applied to a single-wafer-type substrate processing apparatus or a multi-wafer-type substrate processing apparatus. That is, the above-described embodiments were described using an example in which a film is formed by using a batch-type substrate processing apparatus that processes a plurality of wafers at a time. However, the present disclosure is not limited to the above-described embodiments and may be suitably applied to, for example, a case in which a film is formed by using a single-wafer-type substrate processing apparatus that processes one or several substrates at a time. Furthermore, the above-described embodiments were described using an example in which a film is formed by using the substrate processing apparatus including a hot-wall-type process furnace. The present disclosure is not limited to the above-described embodiments and may also be suitably applied to a case in which a film is formed by using a substrate processing apparatus including a cold-wall-type process furnace. Even when these substrate processing apparatuses are used, each process may be performed under the same processing procedures and processing conditions as those of the above-described embodiments and modifications. The same effects as those of the above-described embodiments and modifications may be obtained. The above-described embodiments and modifications may be used in combination as appropriate. The processing procedure and processing conditions of such a case may be, for example, the same as the processing procedures and processing conditions of the above-described embodiments and modifications.

According to the present disclosure in some embodiments, it is possible to reduce horizontal misalignment of substrates caused by deflection of a first boat and a second boat when the substrates are supported by the first boat and the second boat.

While certain embodiments are described, these embodiments are presented by way of example, and are not intended to limit the scope of the disclosure. Indeed, the embodiments described herein may be embodied in a variety of other forms. Furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate holder, comprising:
(a) a first boat configured to hold a plurality of substrates arranged along a predetermined axis; and
(b) a second boat configured to be movable in a direction of the axis relative to the first boat,
wherein the first boat includes (a1) a plurality of first support columns extending in the direction of the axis and supporting the plurality of substrates from outer peripheral sides of the substrates,
wherein the second boat includes (b1) a plurality of second support columns extending in the direction of the axis and supporting the plurality of substrates from the outer peripheral sides of the substrates, the second boat being configured such that the plurality of substrates are delivered from the first boat to the second boat and returned from the second boat to the first boat by moving the second boat relative to the first boat in both directions along the axis, and
wherein an amount and a direction of elastic deformation of at least one selected from the group of the first boat and the second boat when supporting the plurality of substrates are set so that substantially no displacement of the at least one selected from the group of the first boat and the second boat occurs in a perpendicular direction with respect to the direction of the axis after a cycle including the delivery and return of the plurality of substrates is performed one or more times.

2. The substrate holder of claim 1, wherein an arrangement and an amount of elastic deformation of at least one selected from the group of the plurality of first support columns and the plurality of second support columns are set so that, when supporting the plurality of substrates, substantially no displacements of at least one selected from the group of the plurality of first support columns and the plurality of second support columns occur in the perpendicular direction compared to a state before supporting the substrates.

3. The substrate holder of claim 1, wherein the amount and the direction of elastic deformation of the at least one selected from the group of the first boat and the second boat are set so that, when supporting the plurality of substrates, displacements of the first boat and the second boat in the perpendicular direction compared to a state before supporting the plurality of substrates are cancelled out.

4. The substrate holder of claim 1, wherein at least one selected from the group of the plurality of first support columns and the plurality of second support columns is elastically deformed such that, displacements of the at least one selected from the group of the plurality of first support columns and the plurality of second support columns in the direction of the axis when supporting the plurality of substrates are substantially identical compared to a state before supporting the plurality of substrates.

5. The substrate holder of claim 1, wherein the elastic deformation is a deflection deformation caused by compression of at least one selected from the group of the plurality of first support columns and the plurality of second support columns in a longitudinal direction of the at least one selected from the group of the plurality of first support columns and the plurality of second support columns.

6. The substrate holder of claim 1, wherein when a direction perpendicular to the direction of the axis, in which the plurality of substrates are insertable into the first boat, is defined as a front, the plurality of second support columns are configured to be symmetrical in front-rear and left-right directions or rotationally symmetrical with respect to centers of gravity of the substrates.

7. The substrate holder of claim 1, wherein the second boat further includes a plurality of plate-shaped couplers extending perpendicularly to the direction of the axis and configured to couple the plurality of second support columns to one another, and
wherein the plurality of couplers and the plurality of second support columns are rigidly joined to one another.

8. The substrate holder of claim 7, wherein each of the plurality of couplers includes two cutouts corresponding to two first support columns of the plurality of first support columns.

9. The substrate holder of claim 8, wherein when a direction perpendicular to the direction of the axis, in which the plurality of substrates are insertable into the first boat, is defined as a front, the first boat is configured so that the substrates are insertable into the first boat from the front,
wherein the two first support columns are disposed at both sides of the substrates when viewed from centers of the substrates, and
wherein the plurality of second support columns are disposed so as to sandwich the two first support columns in a front-rear direction.

10. The substrate holder of claim 8, wherein a cutout depth of at least one cutout of the cutouts is set so that, by inserting one of the two first support columns into the at least one cutout, a maximum distance between the one of the two first support columns and one second support column of the plurality of second support columns disposed behind the other of the two first support columns is shorter than a shortest distance between the one of the two first support columns and the other of the two first support columns corresponding to the other of the cutouts.

11. The substrate holder of claim 7, wherein a center of gravity of the second boat is on the axis, and one of the plurality of couplers includes a support configured to receive a drive force on the axis.

12. The substrate holder of claim 8, wherein when a direction perpendicular to the direction of the axis, in which the plurality of substrates are insertable into the first boat, is defined as a front, the first boat is configured so that the substrates are insertable into the first boat from the front,
wherein four first support columns of the plurality of first support columns are disposed such that two of the four first support columns are disposed on each of left and right sides of the substrates when viewed from centers of the substrates, and
wherein the plurality of second support columns are disposed so as to be sandwiched by the two of the four first support columns on each of the left and right sides in a front-rear direction.

13. The substrate holder of claim 12, wherein each of the plurality of couplers includes an arm extending in a radial direction of the second boat with a width narrower than a distance between the two first support columns.

14. A substrate processing apparatus, comprising:
a substrate holder including a first boat configured to hold a plurality of substrates arranged along a predetermined axis and a second boat configured to be movable in a direction of the axis relative to the first boat;
a rotator including a rotary shaft configured to support the first boat so as to be rotatable about the axis; and
a driver configured to drive the second boat in the direction of the axis and separate the substrates from the first boat,
wherein the first boat includes a plurality of first support columns extending in the direction of the axis and supporting the plurality of substrates from outer peripheral sides of the substrates,
wherein the second boat includes a plurality of second support columns extending in the direction of the axis and supporting the plurality of substrates from the outer peripheral sides of the substrates, the second boat being configured such that the plurality of substrates are delivered from the first boat to the second boat and returned from the second boat to the first boat by moving the second boat relative to the first boat in both directions along the axis, and
wherein an amount and a direction of elastic deformation of at least one selected from the group of the first boat and the second boat when supporting the plurality of substrates are set so that substantially no displacement of the at least one selected from the group of the first boat and the second boat occurs in a perpendicular direction with respect to the direction of the axis after a cycle including the delivery and return of the plurality of substrates is performed one or more times.

15. A method of processing a substrate, comprising:
(a) a process of accommodating a first boat configured to hold a plurality of substrates arranged along a predetermined axis into a process container;
(b) a process of processing the plurality of substrates in the process container while rotating the first boat by a rotator including a rotary shaft which supports the first boat so as to be rotatable about the axis;
(c) a process of lifting a second boat upward and delivering the plurality of substrates from the first boat to the second boat by a driver capable of driving the second boat in a direction of the axis and separating the plurality of substrates from the first boat; and
(d) a process of, after (c), driving the second boat in the direction of the axis, lowering the second boat downward by the driver, and returning the plurality of substrates from the second boat to the first boat,
wherein an amount and a direction of elastic deformation of at least one selected from the group of the first boat and the second boat when supporting the plurality of substrates are set so that substantially no displacement of the at least one selected from the group of the first boat and the second boat occurs in a perpendicular direction with respect to the direction of the axis after a cycle including (c) and (d) is performed one or more times.

16. A method of manufacturing a semiconductor device comprising the method of claim 15.

17. A non-transitory computer-readable recording medium storing a program that causes, by a computer, a substrate processing apparatus to perform a process comprising the method of claim 15.
